(19) United States
(12) Patent Application Publication
(10) Pub. No.: US 2022/0195238 A1
(43) Pub. Date: Jun. 23, 2022

(54) CHEMICALLY HOMOGENEOUS SILICON HARDMASKS FOR LITHOGRAPHY

(71) Applicant: Brewer Science, Inc., Rolla, MO (US)

(72) Inventors: Reuben T. Chacko, Rolla, MO (US); Tantiboro Ouattara, Eureka, MO (US); Andrea M. Chacko, Rolla, MO (US); Yichen Liang, Rolla, MO (US); Kelsey Brakensiek, Rolla, MO (US)

(21) Appl. No.: 17/559,988

(22) Filed: Dec. 22, 2021

Related U.S. Application Data
(60) Provisional application No. 63/129,807, filed on Dec. 23, 2020.

(51) Int. Cl. C09D 183/04; G03F 7/20; C08G 77/20

(52) U.S. Cl. CPC C09D 183/04; C08G 77/80; C08G 77/20; G03F 7/2004

(57) ABSTRACT

Silicon hardmasks with a single-component polymer are disclosed. These hardmasks provide high optical homogeneity and high chemical homogeneity, thus minimizing or avoiding negative stochastic effects on feature critical dimension. The hardmasks further provide low porosity, higher density, and high silicon content and improve performance factors such as LER/LWR, defectivity, uniformity, and DoF.

### RELATED APPLICATIONS

The present application claims the priority benefit of U.S. Provisional Patent Application Ser. No. 63/129,807, filed Dec. 23, 2020, entitled CHEMICALLY HOMOGENEOUS SILICON HARDMASKS FOR EUV LITHOGRAPHY, incorporated by reference in its entirety herein.

### BACKGROUND

### Field

The present disclosure relates to methods of fabricating microelectronic structures using lithography.

### DESCRIPTION OF RELATED ART

Several technologies such as multilayer-lithography and directed self-assembly (“DSA”) depend on etch to enable transfer of generated patterns to the underlying substrate. However, as feature sizes get smaller, stochastic effects and nanoscale inhomogeneities contribute to sub-optimal lithography and transfer of the patterned resist. These inhomogeneities may be on the order of 0.5-2 nanometers or larger for conventional hardmasks. There is a need for silicon hardmasks (Si-HMs) with superior opto-chemical homogeneity to enable consistent lithography and etch properties.

It has been hypothesized and modeled that homogeneity and distribution of the components play an increasingly important role in the performance of resist materials. For example, in EUV lithography, electron and hole migration between components of the resist, and by extension, the materials in contact with the resist, such as the hardmask, can dictate how uniformly PAGs are activated after EUV electrons have been generated. This becomes increasingly important for future nodes where stochastic effects may contribute to a significant portion of the critical dimension of the feature. Most efforts towards improving opto-chemical homogeneity have been directed towards improving homogeneity and distribution of active components in the resist.

### SUMMARY

The present disclosure is broadly concerned with a method of forming a structure. The method comprises providing a substrate that optionally includes one or more intermediate layers. A composition is applied to the substrate, or on the one or more intermediate layers on the substrate, if present, so as to form a silicon hardmask layer. The composition comprises a first polymer or oligomer formed from a monomer comprising at least two of moiety (I):

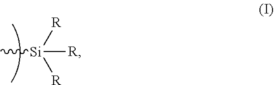

where:
   each R is individually chosen from hydrogen, alkyls, alkoxys, and halogens; and
   “ [symbol] ” represents the point of attachment of the silicon atom to the rest of the monomer.

One or more intermediate layers are optionally formed on the silicon hardmask layer. A photoresist layer is formed on the one or more intermediate layers on the silicon hardmask layer, if present, or on the silicon hardmask layer if no intermediate layer is present. At least a portion of the photoresist layer is subjected to radiation.

In another embodiment, a structure is provided. The structure comprises: a substrate having a surface; one or more optional intermediate layers on the substrate surface; a silicon hardmask layer on the substrate surface, or on the intermediate layers on the substrate surface, if present; one or more optional intermediate layers on the silicon hardmask layer; and a photoresist layer on the one or more intermediate layers on the silicon hardmask layer, if present, or on the silicon hardmask layer if no intermediate layer is present. The silicon hardmask layer comprises a polymer or oligomer that comprises recurring units of one or both of:

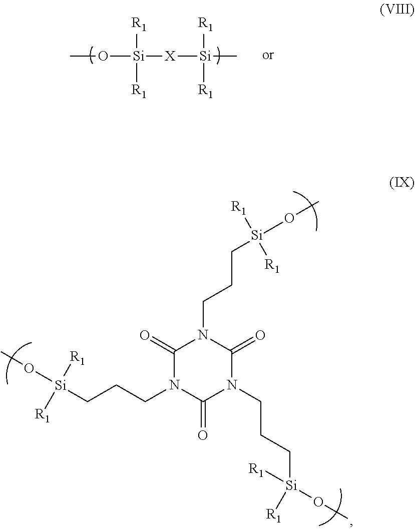

where:
each R₁ is individually chosen from hydrogen, alkyls, alkoxys, halogens, and —O—;

and
X is chosen from:

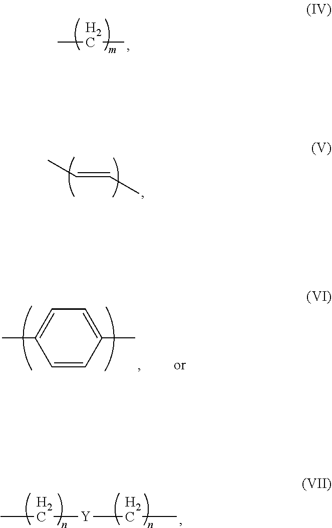

where:
   m is 1 to about 16;
   n is 1 to about 8; and
   each Y is individually chosen from one or more of:

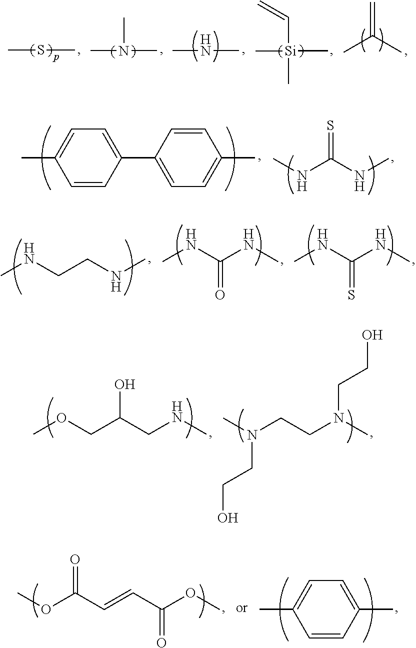

where p is 1 to 6;

### BRIEF DESCRIPTION OF THE DRAWINGS

Figure (FIG. 1(a) is a scanning electron microscope (“SEM,” 150kx) photograph showing dense features formed as described in Example 14;

FIG. 1(b) is an SEM (150kx) photograph showing an isolated feature formed as described in Example 14;

FIG. 2(a) is a graph showing the process window analysis described in Example 15, using the Example 7 hardmask material;

FIG. 2(b) is a graph showing the process window analysis described in Example 15, using a commercially available hardmask material;

FIG. 3(a) is an SEM photograph (150kx) with a top-down view of trenches formed using the Example 7 hardmask material as described in Example 15;

FIG. 3(b) is an SEM photograph (150kx) with a top-down view of trenches formed using a commercially available hardmask material as described in Example 15;

FIG. 4 is the exposure matrix of the hardmask material of Example 13 processed as described in Example 16;

FIG. 5 is an SEM photograph (164kx) with a top-down view of printed lines obtained as described in Example 16;

FIG. 6 is the Bossung curve of the Example 13 hardmask material (see Example 16);

FIG. 7 is the exposure matrix of the hardmask material of Example 18 processed as described in Example 19;

FIG. 8 is an SEM photograph (150kx in the x direction and 49kx in the y direction) with a top-down view of printed L/S features obtained as described in Example 19;

FIG. 9 is the exposure matrix of the hardmask material of Example 18 processed as described in Example 20;

FIG. 10 is an SEM photograph (164kx) with a top-down view of contact holes formed as described in Example 20;

FIG. 11 compares the critical dimension uniformity and SEM images of single- and multiple-monomer polymers (Example 22);

FIG. 12 is a graph depicting the defect-free process window for testing described in Example 22;

FIG. 13 is graph comparing the CF₄ etch rates of the Example 13 hardmask formulation to a conventional hardmask (Example 23); and

FIG. 14 is graph comparing the O₂ etch rates of the Example 13 hardmask formulation to a conventional hardmask (Example 23).

### DETAILED DESCRIPTION

The present disclosure is concerned with silicon hardmask compositions and methods of using those compositions to form microelectronic structures. The compositions are useful at a wide range of wavelengths but are particularly well-suited for EUV lithography processes.

### Silicon Hardmask Compositions

### 1. Polymers or Oligomers for Use in Compositions

Polymers and/or oligomers (i.e., two to ten monomers or repeat units) used in the silicon hardmask (“Si-HM”) compositions are preferably formed by polymerizing and/or oligomerizing monomers comprising one or more of the moiety (I):

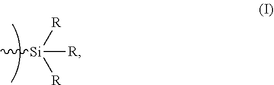

where:
each R is individually chosen (i.e., each R can be the same or different) from hydrogen, alkyls (preferably C₁ to about C₆, and more preferably C₁ to about C₃), alkoxys (preferably C₁ to about C₆, and more preferably C₁ to about C₃), and halogens (preferably —Cl, —F, —Br, and/or —I); and
“ [symbol] ” represents the point of attachment of the silicon atom to the rest of the monomer. In one embodiment, the Si atom is not bonded to an alkoxy group and/or a methyl group at the point of attachment to the rest of the monomer.

Preferably no more than one R in moiety (I) is hydrogen and/or no more than one R in moiety (I) is a halogen. That is, it is preferred that at least two R groups in the moiety (I) are an alkyl and/or alkoxy, and in some embodiments, all three R groups in moiety (I) are alkyls and/or alkoxys.

In some embodiments, the monomer comprises at least two (and preferably three) of moiety (I).

Preferred monomers comprising at least one moiety (I) that can be oligomerized and/or polymerized for use in the Si-HM compositions preferably have a structure chosen from one or both of the following:

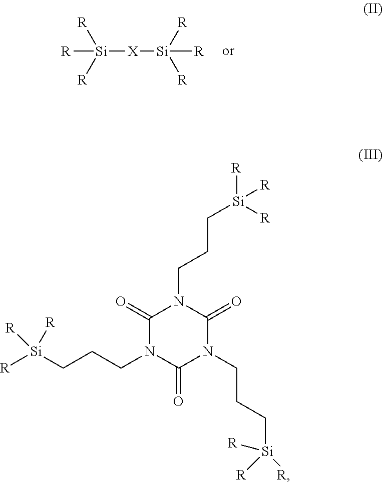

where R is as defined previously (with respect to moiety (I)), and X is chosen from one or more of:

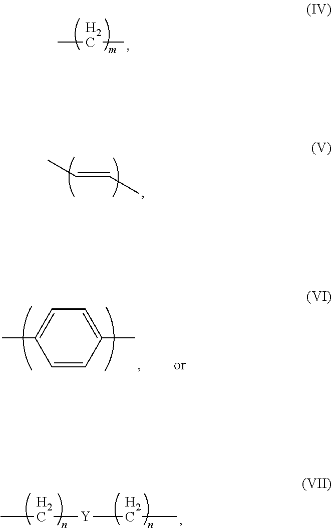

where:
m is 1 to about 16, preferably 1 to about 12, and more preferably 1 to about 8;
n is 1 to about 8, preferably 1 to about 6, and more preferably 1 to about 3; and
each Y is individually chosen from one or more of:

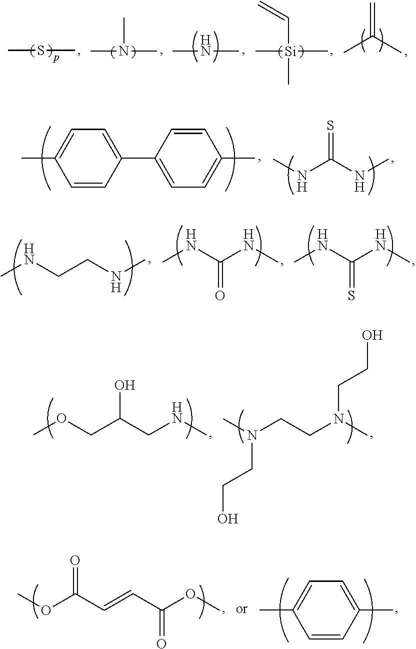

where p is 1 to about 6, and more preferably 1 to about 4.

In one embodiment, the monomers that are polymerized or oligomerized do not include any Si—OH groups.

In another embodiment, the polymer or oligomer comprise less than about 5 mol %, preferably less than about 3 mol %, and more preferably about 0 mol % of 3-(triethoxysilyl)propyl] succinic anhydride monomers.

Examples of monomers that can be polymerized or oligomerized for inclusion in a Si-HM composition as described herein include those selected from the group consisting of 1,2-bis(triethoxysilyl)ethylene, 1,2-bis(methyldiethoxysilyl)ethylene, 1,1-bis(trimethoxysilylmethyl)-ethylene, 1,6-bis(trimethoxysilyl)hexane, 1,4-bis(triethoxysilyl)benzene, 1,2-bis(trimethoxysilyl)-ethane, n,n′-bis[3-(triethoxysilyl)propyl]urea, n,n′-bi s[3-(triethoxysilyl)propyl]thiourea, 1,8-bis(triethoxysilyl)octane, bis(triethoxysilyl)methane, bis(trimethoxysilylethyl)benzene, 1,3-bis(chlorodimethylsilyl)propane, 1,2-bis(chlorodimethylsilyl)ethane, bis[3-(triethoxysilyl)-propyl]disulfide, n,n′-bis[(3-trimethoxysilyl)propyl]ethylenediamine, n,n′-bis(2-hydroxyethyl)-n,n′-bis(trimethoxysilylpropyl)ethylenediamine, bis(methyldimethoxysilylpropyl)-n-methyl-amine, bis[3-(triethoxysilyl)propyl]tetrasulfide, bis(triethoxysilylethyl)-vinylmethylsilane, bis(3-trimethoxysilylpropyl) fumarate, 4,4′-bis(dimethylsilyl)biphenyl, n,n′-bis(3-trimethoxysilylpropyl)thiourea, 1,11-bis(trimethoxysilyl)-4-oxa-8-azaundecan-6-ol, bis(methyldiethoxysilylpropyl)amine, tris[3-(trimethoxysilyl)propyl] isocyanurate, and combinations thereof.

### 2. Polymerization Materials and Methods

To synthesize the polymer, the desired monomer(s) is charged to a reactor with an optional distillation apparatus or reflux setup in an appropriate polymerization solvent with stirring. Polymerization solvents include propylene glycol monomethyl ether acetate (“PGMEA”), propylene glycol methyl ether (“PGME”), acetone, propylene glycol ethyl ether (“PGEE”), cyclohexanone, ethyl lactate, 3-methyl-1,5-pentanediol, 1,2-propylene glycol, 1,3-propylene glycol, ethylene glycol, and mixtures thereof. Monomer percent solids in the reaction mixture are preferably from about 10% to about 40%, and more preferably from about 25% to about 35%, based on the combined weight of the reaction mixture (including monomers, catalysts, and solvent(s) taken as 100% by weight. A catalyst is then slowly charged to the reactor at a temperature of about 20° C. to about 100° C., and preferably about 25° C. to about 85° C.

Suitable catalysts for solgel polymerization include, but are not limited to, nitric acid, hydrochloric acid, acetic acid, trifluoroacetic acid, sulfonic acid, and combinations thereof. The catalyst is added as a solution in water. The catalyst solutions are prepared in water preferably as about 0.001N to about 10N solutions, more preferably about 0.01N to about 5N solutions, and even more preferably about 3N solutions for weaker acids and about 0.01N solutions for stronger acids. These aqueous catalyst solutions are added in an amount of preferably about 0.5 equivalents to about 20 equivalents, more preferably about 5 equivalents to about 15 equivalents, and even more preferably about 10 equivalents to the total monomers, where one equivalent is approximately equal to one mole of water per mol of monomer (or to about 18 grams of water per mole of monomer). The reaction mixture is allowed to stir preferably from about 10 minutes to about 300 minutes, more preferably from about 10 minutes to about 60 minutes, even more preferably from about 10 minutes to about 30 minutes. The reaction is optionally performed in an inert atmosphere such as nitrogen.

In one embodiment, the polymer is purified and/or isolated by a rotary evaporator process (also referred to as “rotavap” or “rotavaped” herein). In this process, the reaction mixture is processed in a rotary evaporator and is processed at a temperature of from about 30° C. to about 100° C., preferably from about 45° C. to about 55° C. The rotary evaporation process is performed until the solvent is removed. Prior to rotary evaporation, a cosolvent may be added to the reaction mixture, if desired. Suitable cosolvents include, but are not limited to, PGEE, PGMEA, PGME, and combinations thereof.

The formed polymer will preferably include recurring units of one or both of the following:

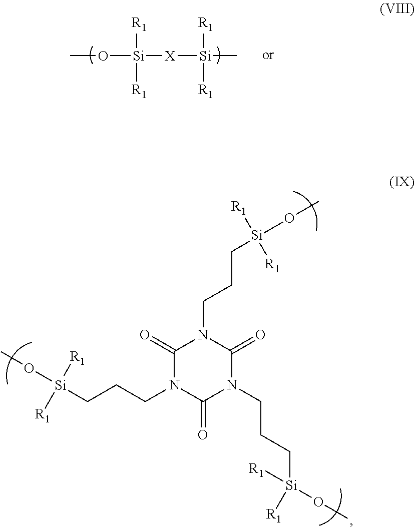

where:
X is as defined previously; and
each R₁ is individually chosen from:
   hydrogen;
   alkyls (preferably C₁ to about C₆, and more preferably C₁ to about C₃);
   alkoxys (preferably C₁ to about C₆, and more preferably C₁ to about C₃);
   halogens (preferably —Cl, —F, —Br, and/or —I); and
   —O—.

In one embodiment, it is preferred that polymer or oligomer consists essentially of, or even consists of, a single monomer type. That is, the resulting polymer or oligomer is formed largely from a single type of monomer (i.e., the same monomers), thus largely containing a single type of recurring unit (i.e., the same recurring units). As used herein, monomers are considered to be the same or of a single type as long as there are not any chemical structural differences between them (notwithstanding minor impurities or imperfections that might inherently be present). Recurring units of a polymer or oligomer are considered to be the same or of a single type if they each comprise identical X groups (in cases of Structure (VIII)), or each comprise

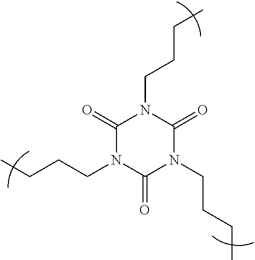

in cases of Structure (IX).

In one embodiment, the monomers that are polymerized or oligomerized do not include any Si—OH groups.

In one embodiment, at least about 95 mol %, more preferably at least about 97 mol %, even more preferably at least about 99%, and most preferably about 100 mol % of the polymer or oligomer is formed of a single monomer type.

In some embodiments, the resulting polymer or oligomer has a high silicon content. The polymer or oligomer is preferably from about 20% silicon to about 47% silicon, and more preferably from about 35% to about 45% silicon, where the silicon percent is calculated by the molecular weight of the silicon as a percentage of the molecular weight of the fully hydrolyzed polymer. The weight-average molecular weight (Mw) range of the polymer is preferably from about is 500 Daltons to about 50,000 Daltons, more preferably from about 1,000 Daltons to about 10,000 Daltons, as determined by gel permeation chromatography (GPC) using polystyrene standards.

### 3. Composition Preparation

The polymer and/or oligomer is then dispersed or dissolved in a solvent system. Preferred solvent systems include one or more solvents such as PGMEA, PGME, PGEE, propylene glycol n-propyl ether (“PnP”), ethyl lactate, cyclohexanone, gamma-butyrolactone (“GBL”), 3-methyl-1,5-pentanediol, 1,2-propylene glycol, 1,3-propylene glycol, ethylene glycol, and/or mixtures thereof. The solvent system is preferably utilized at a level of from about 95% to about 99.9% by weight, more preferably from about 97.5% to 99.9%, and even more preferably from about 99% to about 99.9% by weight, based upon the total weight of the composition taken as 100% by weight. The compositions used to form the silicon hardmask layers will preferably comprise a solids content of from about 0.1% to about 5% by weight solids, more preferably from about 0.1% to about 2.5% by weight solids, and even more preferably from about 0.1% to about 1% by weight solids, based upon the total weight of the composition taken as 100% by weight.

In one embodiment, the composition comprises less than about 3% by weight, preferably less than about 1% by weight, and preferably 0% by weight of polymers other than the above-described polymer, based on the total weight of solids in the composition.

In another embodiment, the composition comprises less than about 3% by weight, preferably less than about 1% by weight, and preferably 0% by weight of an organic polymer, based on the total weight of solids in the composition.

Mixing the above ingredients together in the solvent system forms the silicon hardmask layer composition. Furthermore, any optional ingredients (e.g., surfactants, mineral acids, organic acids, grafting/condensation catalysts, thermal acid generators (“TAGs”), photoacid generators (“PAGs”), inhibitors, and/or pH regulators), are also dispersed in the solvent system at the same time.

When used, suitable TAGs include, but are not limited to, blocked acids such as quaternary ammonium blocked triflic acid, such as those sold under the name K-PURE® TAG-2689, K-PURE® TAG-2678, (King Industries, Inc., Norwalk, Conn.), TAG-2700, CXC-1889, TAG-2789, and combinations thereof. The TAG is present in the composition in an amount of about 0.01% to about 1% by weight, more preferably about 0.05% to about 0.5% by weight, and even more preferably from about 0.1% to about 0.3% by weight, based upon the total weight of the composition taken as 100% by weight.

When used, suitable catalysts include, but are not limited to, ethyltriphenylphosphonium bromide (“EtPPB”), benzyltriethylammonium chloride (“BTEAC”), tetrabutyl phosphonium bromide (“TBPB”), and combinations thereof. The catalyst is present in the composition in an amount of about 0.001% to about 5% by weight, more preferably about 0.005% to about 1% by weight, and even more preferably about 0.01% to about 0.05% by weight, based upon the total weight of the composition taken as 100% by weight.

When used, suitable inhibitors include those that protect double bonds (e.g., hydroquinone), those that maintain stability of a solgel and/or slow aging (e.g., 3-methyl-1,5-pentanediol), and combinations thereof. Inhibitors may be included to slow aging and/or improve spin-bowl compatibility. The inhibitor is present in the composition in an amount from about 0.001% to about 1.0% by weight, more preferably from about 0.001% to about 0.1% by weight, and even more preferably from about 0.001% to about 0.01% by weight, based upon the total weight of the composition taken as 100% by weight.

When used, suitable pH regulators include maleic acid, malonic acid, malic acid, and combinations thereof. The pH regulators may be included to slow aging and/or improve spin-bowl compatibility. When utilized, the pH regulator is present in the composition in an amount of about 0.001% to about 1.0% by weight, more preferably about 0.001% to about 0.1% by weight, and even more preferably about 0.001% to about 0.01% by weight, based upon the total weight of the composition taken as 100% by weight.

In one embodiment, the silicon hardmask composition consists essentially of, or even consists of the above-described polymer/oligomer, one or more of the above optional ingredients, and solvent system. In a further embodiment, the silicon hardmask composition consists essentially of, or even consists of, the above-described polymer/oligomer, solvent system, and one or more of a catalyst, an acid generator, a radical inhibitor, or a pH regulator. In a further embodiment, the silicon hardmask composition consists essentially of, or even consists of, the above-described polymer/oligomer and solvent system.

### Methods of Using the Silicon Hardmask Compositions

A method of forming a microelectronic structure that is particularly suited for lithography is also provided wherein a hardmask composition as described above is formed into a layer on a substrate surface, or on an intermediate layer (described below) present on the substrate surface.

Any microelectronic substrate can be utilized. The substrate is preferably a semiconductor substrate, such as silicon, SiGe, SiO₂, Si₃N₄, SiON, SiCO:H (such as that sold under the name Black Diamond, by SVM, Santa Clara, Calif., US), tetramethyl silate and tetramethyl-cyclotetrasiloxane combinations (such as that sold under the name CORAL), aluminum, tungsten, tungsten silicide, gallium arsenide, germanium, tantalum, tantalum nitride, Ti₃N₄, hafnium, HfO₂, ruthenium, indium phosphide, coral, glass, or mixtures of the foregoing. The substrate can have a planar surface, or it can include topographic features (via holes, trenches, contact holes, raised features, lines, etc.). As used herein, “topography” refers to the height or depth of a structure in or on a substrate surface.

The substrate surface may be primed prior to hardmask or other layer formation, if desired. Preferred primers include hexamethyldisilizane (“HMDS”). In this process, the wafer is exposed to vapor of the primer in a sealed chamber while heating at 150° C. for 90 seconds. As used herein, a primed surface is considered to be an intermediate layer, even if the priming process simply results in a surface modification of the layer being primed rather than the formation of a distinct layer.

As noted above, optional intermediate layers may be formed on the (primed or unprimed) substrate prior to hardmask layer formation. A carbon-rich layer is one optional layer that may be formed on top of the substrate or any intermediate layers. The carbon-rich layer can be formed by any known application method, with one preferred method being spin-coating at speeds from about 1,000 to about 5,000 rpm, preferably from about 1,250 to about 1,750 rpm, for a time period of from about 30 to about 120 seconds, preferably from about 45 to 75 seconds. The term “carbon-rich” refers to layers formed from compositions comprising greater than about 50% by weight carbon, preferably greater than about 70% by weight carbon, and more preferably from about 75 to about 80% by weight carbon, based upon the total solids in the composition taken as 100% by weight. Suitable carbon-rich layers are selected from the group consisting of spin-on carbon layers (“SOC”), amorphous carbon layers, and carbon planarizing layers.

Exemplary carbon-rich layers will generally comprise a polymer dissolved or dispersed in a solvent system, along with the following optional ingredients: acid and/or base quenchers, catalysts, crosslinking agents, and surface modification additives. Preferred compositions will be suitable for forming thick layers and preferably have solids content of from about 0.1% to about 70%, more preferably from about 5% to about 40%, and even more preferably from about 10% to about 30% by weight, based upon the total weight of the composition taken as 100% by weight. After the carbon-rich composition is applied, it is preferably heated to a temperature from about 100° C. to about 400° C., and more preferably from about 160° C. to about 350° C. and for a time period of from about 30 seconds to about 120 seconds, preferably from about 45 seconds to about 60 seconds, to evaporate solvents. The thickness of the carbon-rich layer after baking is preferably from about 10 nm to about 120 nm, more preferably from about 20 nm to about 100 nm, and even more preferably from about 50 nm to about 60 nm. The carbon-rich layer may be formed by other known application methods, such as chemical vapor deposition (“CVD”), plasma-enhanced chemical vapor deposition (“PECVD”), atomic layer deposition (“ALD”), or plasma-enhanced atomic layer deposition (“PEALD”).

The inventive silicon hardmask layer can be formed by any known application method, either directly on the substrate surface (primed or unprimed) or on the carbon-rich layer, if utilized. One preferred application method involves spin-coating the hardmask composition at speeds from about 1,000 rpm to about 2,000 rpm, preferably from about 1,250 to about 1,750 rpm, for a time period of from about 15 seconds to about 120 seconds, preferably from about 30 seconds to about 75 seconds. After the silicon hardmask composition is applied, it is preferably heated to a temperature of about 150° C. to about 300° C., and more preferably about 200° C. to about 250° C. and for a time period of about 15 seconds to about 120 seconds, preferably about 30 seconds to about 75 seconds, to evaporate solvents. The thickness of the hardmask layer after baking is preferably from about 2 nm to about 50 nm, more preferably from about 5 nm to about 30 nm, and even more preferably from about 10 nm to about 25 nm. The hardmask layer should have an etch rate at least 1.5 times that of the photoresist (e.g., a chemically amplified, metal oxide, or chain scission-type photoresist) in a fluorine-rich (e.g., CF₄) plasma atmosphere, and the SOC or carbon-rich layer should etch at least 1.5 times faster than the hardmask layer in an oxygen-rich (e.g., O₂) plasma etch atmosphere. The hardmask layer should have an etch rate in O₂ that is slow enough to act as an etch block and allow pattern transfer into the SOC or carbon layer.

In one embodiment, when etched in O₂, the hardmask layer will have an etch rate with a reduced variation as compared to layers with multiple-monomer polymers, even when similar functional groups are used. That is, the standard deviation when three etch rate measurements are carried out as described in Example 23 will be less than about 0.5 nm/min, preferably less than about 0.25 nm/min, and more preferably less than about 0.15 nm/min.

The silicon hardmask layer will have good optical and chemical homogeneity, that is, the monomer ratio of the hardmask layer of one sample will preferably be at least 90% the same as the monomer ratio of the hardmask layer of a second sample, more preferably at least 99%, and even more preferably from about 99.9% to about 100%. This will ensure that the density of the functional groups throughout the polymer and the layer will be substantially uniformly, and preferably completely uniformly, distributed.

In one embodiment, the silicon hardmask layer will exhibit high critical dimension uniformity (“CDU”), which is determined as described in Example 22. That is, the CDU will be less than about 5 nm, preferably less than about 3 nm, and even more preferably about 1 nm to about 2.5 nm.

In one embodiment, the silicon hardmask layer will preferably have a surface energy of about 20 mN/m to about 70 mN/m, and more preferably from 25 mN/m to about 60 mN/m, determined by performing surface contact angle measurements with multiple liquids on a contact angle tool such as a VCA Optima contact angle tool.

After the silicon hardmask layer is baked, a photoresist (i.e., imaging layer) can be applied to the silicon hardmask layer to form a photoresist layer. The photoresist layer can be formed by any conventional method, with one preferred method being spin coating the photoresist composition at speeds of from about 350 rpm to about 4,000 rpm (preferably from about 1,000 rpm to about 2,500 rpm) for a time period of from about 10 seconds to about 60 seconds (preferably from about 10 seconds to about 30 seconds). The photoresist layer is then optionally post-application baked (“PAB”) at a temperature of at least about 70° C., preferably from about 80° C. to about 150° C., and more preferably from about 100° C. to about 150° C., and for time periods of from about 30 seconds to about 120 seconds. The thickness (average measurements taken over five locations by an ellipsometer) of the photoresist layer after baking will typically be from about 5 nm to about 120 nm, preferably from about 10 nm to about 50 nm, and more preferably from about 20 nm to about 40 nm.

A priming process may be applied before coating the photoresist. Preferred primers include hexamethyldisilizane. In this process, the wafer is exposed to vapor of the primer in a sealed chamber while heating at 150° C. for 90 seconds.

The photoresist layer is subsequently patterned by exposure to radiation at wavelengths preferably of from about 10 nm to about 400 nm, more preferably from about 13 nm to about 193 nm. In one embodiment, the layer is exposed to EUV radiation (i.e., wavelengths of less than about 20 nm and generally about 13.5 nm). Regardless, the preferred exposure dose is about 5 mJ/cm² to about 120 mJ/cm², preferably from about 10 mJ/cm² to about 80 mJ/cm², and more preferably from about 20 mJ/cm² to about 60 mJ/cm². More specifically, the photoresist layer is exposed using a mask positioned above the surface of the photoresist layer. The mask has areas designed to permit the radiation to reflect from (in the case of EUV) or pass through (in the case of ArF or higher wavelengths) the mask and contact the surface of the photoresist layer. The remaining portions of the mask are designed to absorb the light to prevent the radiation from contacting the surface of the photoresist layer in certain areas. Those skilled in the art will readily understand that the arrangement of reflecting and absorbing portions is designed based upon the desired pattern to be formed in the photoresist layer and ultimately in the substrate or any intermediate layers.

After exposure, the photoresist layer is preferably subjected to a post-exposure bake (“PEB”) at a temperature of less than about 180° C., preferably from about 60° C. to about 140° C., and more preferably from about 80° C. to about 130° C., for a time period of from about 30 seconds to about 120 seconds (preferably from about 30 seconds to about 90 seconds).

The photoresist layer is then contacted with a developer to form the pattern. Depending upon whether the photoresist used is positive-working or negative-working, the developer will either remove the exposed portions of the photoresist layer or remove the unexposed portions of the photoresist layer to form the pattern. The pattern is then transferred to the silicon hardmask layer, any present intermediate layers, and finally the substrate. This pattern transfer can take place via plasma etching (e.g., CF₄ etchant, O₂ etchant) or a wet etching or developing process. In embodiments where the pattern will be transferred from the photoresist layer to the substrate via etching, it is preferred that the etch rate of the silicon hardmask layer relative to a typical photoresist is at least about 1×, and preferably from about 1.5× to about 2×.

Regardless of whether pattern transfer is carried out by etching or by developing, the resulting features have high resolutions. For example, resolutions of less than about 40 nm half pitch, and preferably less than about 30 nm half pitch, and even more preferably less than about 20 half pitch, can be achieved with the inventive method. The silicon hardmask layer preferably will improve collapse margin of the final features. Collapse margin is quantified by difference from the dose to size from the maximum dose at which structures are still standing for a positive-tone imaging resist, or the minimum dose in the case of negative-tone development resist or negative-tone imaging resist.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone;

C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Synthesis of Poly(1,2-Bis(triethoxysilyl)ethylene)

In a 250-ml 3 neck round bottom flask, 10.08 grams of 1,2-bis(triethoxysilyl)ethylene (Gelest, Morrisville, Pa.) and 84.88 grams of acetone were added. A stir bar was added to the mixture, and while stirring, 5.15 grams of 0.01 N HCl were added dropwise. After 2.5 hours of reaction time, 84 grams of PGEE (Fujifilm Ultra Pure Solutions, Carrollton, Tex.) were added to the flask, and the mixture was rotavaped to remove acetone. This mother liquor was used in further testing in later examples.

### Example 2

### Formulation of Si-HM with Example 1 Polymer

In a 250-ml Aicello bottle, 1.57 grams of the polymer synthesized in Example 1, 0.02 gram of K-PURE® TAG-2689 (King Industries Inc, Norwalk, Conn.), 78.81 grams of PGEE and 19.7 grams of PGME (KMG Electronic Chemicals, Fort Worth, Tex.) were added and mixed together for 30 minutes. This formulation was filtered using a 0.1-micron PTFE filter (GE Healthcare UK Limited, Buckinghamshire, UK).

### Example 3

### Synthesis of Poly(1,2-Bis(triethoxysilyl)ethylene)

In a 250-ml Aicello bottle, 12.04 grams of 1,2-bis(triethoxysilyl)ethylene and 101.9 grams of acetone were added. Next, 6.21 grams of 0.01 N HCl were added dropwise while mixing the contents of the bottle. The mixture was allowed to tumble and mix on a wheel for 3 hours at room temperature, after which 102 grams of PGEE was added. The mixture was transferred into a 500-ml round bottom flask. The mixture was rotavaped at room temperature for 5 minutes and submerged in the rotavap water bath kept at 50° C. until distillation of acetone was stopped. Rotavap was continued for an additional 5 minutes. The mixture was cooled to room temperature, and the mother liquor was filtered using a 0.2-micron PTFE filter.

### Example 4

### Formulation of Si-HM with Example 3 Polymer

In a 250-ml Aicello bottle, 0.603 gram of the mother liquor synthesized in Example 3, 0.006 gram of ethyltriphenylphosphonium bromide (“EtPPB,” catalyst obtained from Sigma-Aldrich Inc., St. Louis, Mo.), 78.72 grams of PGEE, and 20.67 grams of PGME were added and mixed together for 30 minutes. This formulation was filtered using a 0.1-micron PTFE filter.

### Example 5

### Formulation of Si-HM with Example 3 Polymer

In a 100-ml Aicello bottle, 0.347 gram of the mother liquor synthesized in Example 3, 0.003 gram of EtPPB, 79.727 grams of PGEE, and 19.923 grams of PGME were added and mixed together for 30 minutes. This formulation was filtered using a 0.1-micron PTFE filter.

### Example 6

### Synthesis of Poly(1,2-bis(methyldiethoxysilyl)ethylene)

In a 500-ml round bottom flask, 10.09 grams of 1,2-bis(methyldiethoxysilyl)ethylene (Gelest, Morrisville, Pa.) and 83.87 grams of acetone were added. Next, 6.2 grams of 0.01 N HCl were added dropwise while stirring at room temperature for 30 minutes. The mixture was heated to reflux at 80° C. for 4 hours, after which 84 grams of PGEE were added to the reaction flask. The mixture was rotavaped at room temperature for 5 minutes and submerged in the rotavap water bath kept at 50° C. until distillation of acetone stopped. Rotavap was continued for an additional 5 minutes. The mixture was cooled to room temperature and stored at −20° C.

### Example 7

### Formulation of Si-HM with Example 6 Polymer

In a 250-ml Aicello bottle, 1.67 grams of the mother liquor synthesized in Example 6, 0.02 gram of benzyltriethylammonium chloride (“BTEAC,” catalyst obtained from Sigma-Aldrich Inc., St. Louis, Mo.), 78.62 grams of PGEE, and 19.69 grams of PGME were added and mixed together for 30 minutes. This formulation was filtered using a 0.1-micron PTFE filter.

### Example 8

### Synthesis of Poly(1,2-bis(methyldiethoxysilyl)ethylene)

In a 250-ml 3-neck round bottom flask, 5.18 grams of 1,2-bis(methyldiethoxysilyl)ethylene and 43.46 grams of PGMEA were added. Next, 3.21 grams of 0.01M HCl were added dropwise while stirring at room temperature for 30 minutes. The mixture was heated to reflux at 80° C. for 4 hours. The mixture was cooled to room temperature, transferred to a clean Aicello bottle, and stored at −20° C.

### Example 9

### Formulation of Si-HM with Example 8 Polymer

In a 250-ml Aicello bottle, 35.32 grams of the mother liquor synthesized in Example 8, 0.883 gram of 1% hydroquinone (radical inhibitor) in PGMEA (KMG Electronic Chemicals, Fort Worth, Tex.), 211.31 grams of PGMEA, and 2.48 grams of 3-methyl-1,5-pentanediol (Sigma-Aldrich Inc., St. Louis, Mo.) were added and mixed together for 30 minutes. This formulation was filtered using a 0.1-micron PTFE filter.

### Example 10

### Synthesis of Poly(1,4-Bis(triethoxysilyl)benzene)

In a 100-ml round bottom flask, 1.50 grams of 1,4-bis(triethoxysilyl)benzene (Gelest, Morrisville, Pa.) and 12.83 grams of PGMEA were added. Next, 0.67 gram of 0.01 M HCl was added dropwise while stirring the contents of the flask. The mixture was allowed to stir for 30 minutes at room temperature. The solution was then purged with nitrogen in a reflux setup and heated to 80° C. for 6 hours while stirring constantly. The mother liquor was then removed from the heat to cool while stirring. Once at room temperature, the mother liquor was poured into a 100-ml Aicello bottle for storage.

### Example 11

### Formulation of Si-HM with Example 10 Polymer

In a 100-ml Aicello bottle, 8.2931 grams of the mother liquor synthesized in Example 10, 10.0109 grams of PGME, and 82.7083 grams of PGMEA were added and mixed together for 30 minutes. This formulation was filtered using a 0.1-micron filter.

### Example 12

### Synthesis of Poly(1,2-Bis(methyldiethoxysilyl)ethylene)

In a 100-ml round bottom flask, 7.83 grams of 1,2-bis(methyldiethoxysilyl)ethylene (Gelest, Morrisville Pa.), and 65.34 grams of PGMEA were added. Next, 4.85 grams of 0.01 M HCl were added dropwise while stirring the contents of the flask. The mixture was allowed to stir for 30 minutes at room temperature, after which the solution was purged with nitrogen in a reflux setup and heated to 80° C. for 6 hours while stirring constantly. The mother liquor was then removed from the heat to cool while stirring. Once room temperature, the mother liquor was poured into a 100-ml Aicello bottle for storage.

### Example 13

### Formulation of Si-HM with Example 12 Polymer

In a 100-ml Aicello bottle, 11.9434 grams of the mother liquor synthesized in Example 12, 0.2985 gram of TBPB (Sigma-Aldrich Inc., St. Louis, Mo.), 9.5819 grams of PGME, and 78.1605 grams of PGMEA were added and mixed together for 30 minutes. This formulation was filtered using a 0.1-micron filter.

### Example 14

### Screening of Negative Tone Development Lithographic Performance

Using a Sokudo DUO track, 12-inch silicon wafers were dehydrated at 230° C. for 60 seconds and primed with hexamethyldisilizane at 110° C. for 50 seconds prior to SOC coating. A spin-on carbon or “SOC” composition sold under the name OptiStack® SOC110D (Brewer Science, Rolla, Mo.) was spin coated onto the primed wafers at 1,727 rpm for 30 seconds followed by a bake at 205° C. for 60 seconds. Silicon hardmasks were then spin coated onto different SOC-coated wafers as follows: The Example 2 formulation was spin coated at 1,280 rpm for 30 seconds, followed by a bake at 240° C. for 60 seconds; and the Example 4 formulation was spin coated at 1,000 rpm for 30 seconds followed by a bake of 205° C. for 60 seconds. The hardmask-coated stacks were primed with hexamethyldisilizane at 150° C. for 80 seconds. A photoresist (AN02 resist from FujiFilm) was applied on top of the stack (on the primed hardmasks) at a spin speed of 1,930 rpm for 30 seconds followed by post-apply bake at 90° C. for 60 seconds. The wafers were exposed through a reticle to create a focus dose matrix using an immersion tool (TWINSCAN NXT:1950i, available from ASML, the Netherlands). For the Example 2 hardmask formulation, the dose was varied from 18 mJ/cm² to 46 mJ/cm², and the focus was varied from −0.23 μm to 0.13 μm. For the Example 4 hardmask formulation, the dose was varied from 18 mJ/cm² to 46 mJ/cm², and the focus was varied from −0.21 μm to 0.11 μm. This was followed by a develop step using FN-DP001/20 developer (FujiFilm, North Kingstown, R.I.).

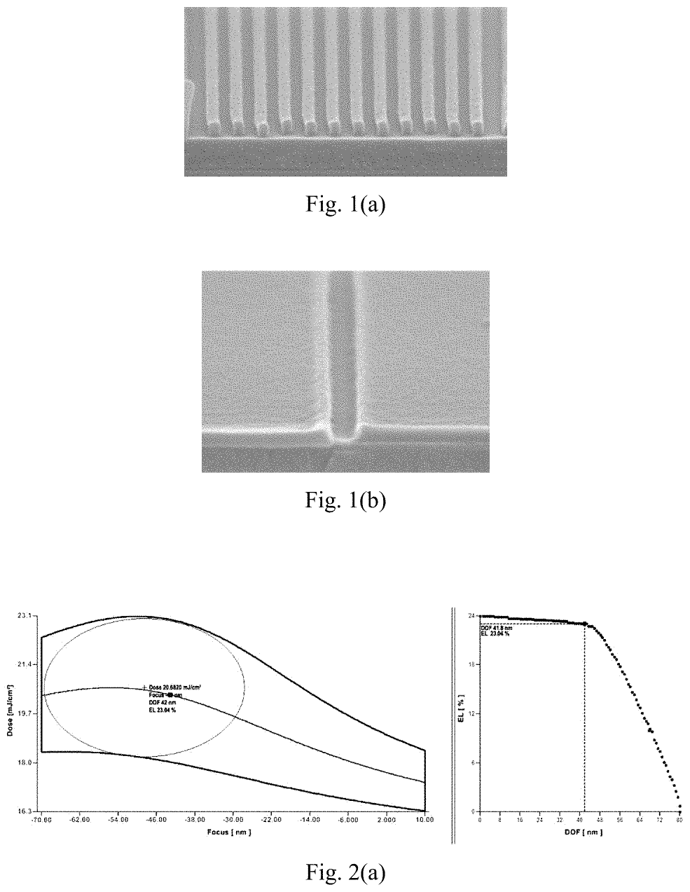

CD-SEM measurements (Hitachi CG5000-2, 150Kx; Beam=500 V, 8 Pa) were carried out to evaluate performance of these hardmasks. The data is shown in Table 1, while FIGS. 1(a)-(b) show images of the formed trenches, which are clean. The resist profiles were also straight on both dense (FIG. 1(a)) and isolated (FIG. 1(b)) features.

TABLE 1
Performance Metrics Obtained for High Opto-Chemical Homogeneity Hardmasks

| | Nested | Nested | Dense | Collapse | Bridge | Iso DoF | Iso |
|---|---|---|---|---|---|---|---|
| | DoF | biased | dose | margin | margin | (nm) @ | LWR |
| Hardmask | (nm) | LWR (nm) | (mJ) | (mJ) | (mJ) | dense dose | (nm) |
| Example 2 | >280 | 3.9 | 32 | 28 | 45 | >40 | 4.4 |
| | (focus shifted) | | | | | | |
| Example 4 | >360 | 3.7 | 32 | 22 | 46 | 80 | 4.8 |

### Example 15

### Screening of Positive Tone Development Lithographic Performance

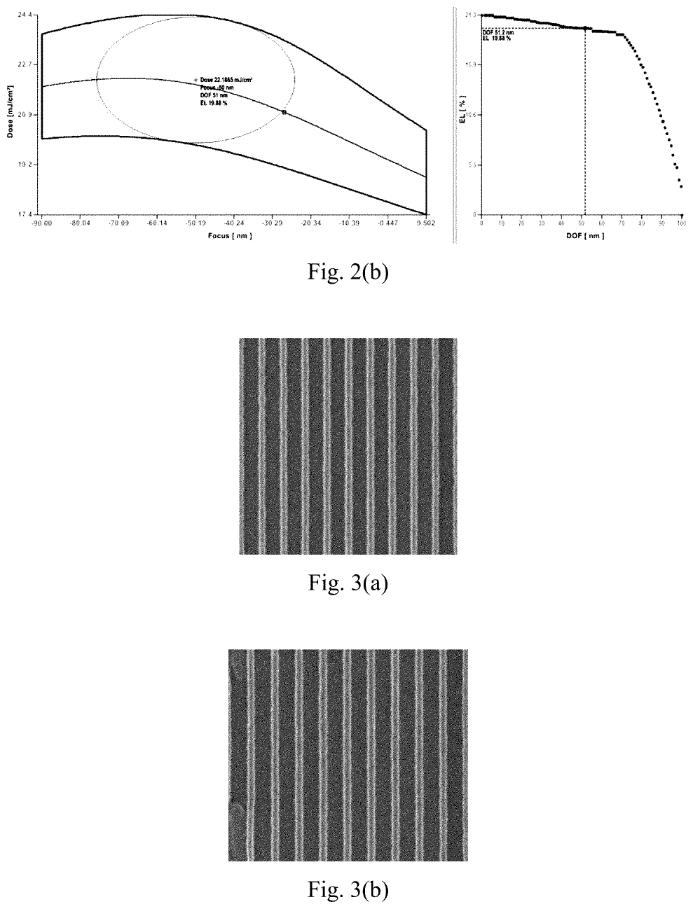

Using a Sokudo DUO track, 12-inch silicon wafers were dehydrated at 230° C. for 60 seconds and primed with hexamethyldisilizane at 110° C. for 50 seconds prior to SOC coating. An SOC sold under the name OptiStack® SOC120 material (Brewer Science, Rolla, Mo.) was spin coated onto the primed wafers at 1,368 rpm for 30 seconds followed by a bake at 205° C. for 60 seconds. Silicon hardmasks were then spin coated onto different SOC-coated wafers as follows: Example 7 at 1,110 rpm for 30 seconds followed by a bake at 205° C. for 60 seconds, and a commercially available hardmask composition sold under the name OptiStack® HM825-303.2 (Brewer Science, Rolla, Mo.) at 1,171 rpm for 30 seconds followed by a bake for 205° C. for 60 seconds. Both hardmasks were coated to a target thickness of 30 nm. A commercially available resist (AIM5484, JSR Micro, Inc.) was applied on top of the stack at a spin speed of 1,185 rpm for 30 seconds followed by post-apply bake at 120° C. for 60 seconds. The wafers were then exposed through a reticle (TM07-40) to create a focus dose matrix using an immersion tool (TWINSCAN NXT:1950i). Sigma (outer/inner) was (0.98/0.821). Illumination mode of Dipole35Y Gen2 was used. NA was 1.35. For the hardmask formulation from Example 7, the dose was varied from 6.4 mJ/cm² to 28.8 mJ/cm², and the focus was varied from 0.15 μm to −0.21 μm. After exposure, a 100° C. bake for 60 seconds was carried out. The pattern was then developed with a developer (OPD262, available from FujiFilm) for 20 seconds. This exposure created a series of trenches and spaces. These features were analyzed using a scanning electron microscope (CG5000-2, Hitachi) using 500 V and 8 pA at 150Kx magnification. The data is shown in Table 2. As shown in FIGS. 2(a) and (b), the process window of the material formulated in Example 7 is larger than that of the commercially available silicon hardmask layer (Opti Stack® HM825-303.2). FIGS. 3(a) and (b) top-down views of both samples.

TABLE 2
Performance Metrics Obtained from Example 7 Hardmask and Commercial Hardmask

| | Dense | PW | PW | Dense | Dense | Collapse | Bridge |
|---|---|---|---|---|---|---|---|
| | DoF | DoF | EL | LWR | Dose | margin | margin |
| Hardmask | (nm) | (nm) | (%) | (nm) | (mJ) | (mJ) | (mJ) |
| Example 7 | 80 | 51 | 19.9 | 3.7 | 20.8 | 25.6 | 10.4 |
| Commercial Hardmask | 60 | 42 | 23.0 | 3.4 | 19.2 | 23.2 | 9.6 |

### Example 16

### Lithography Results of the Formulation from Example 13

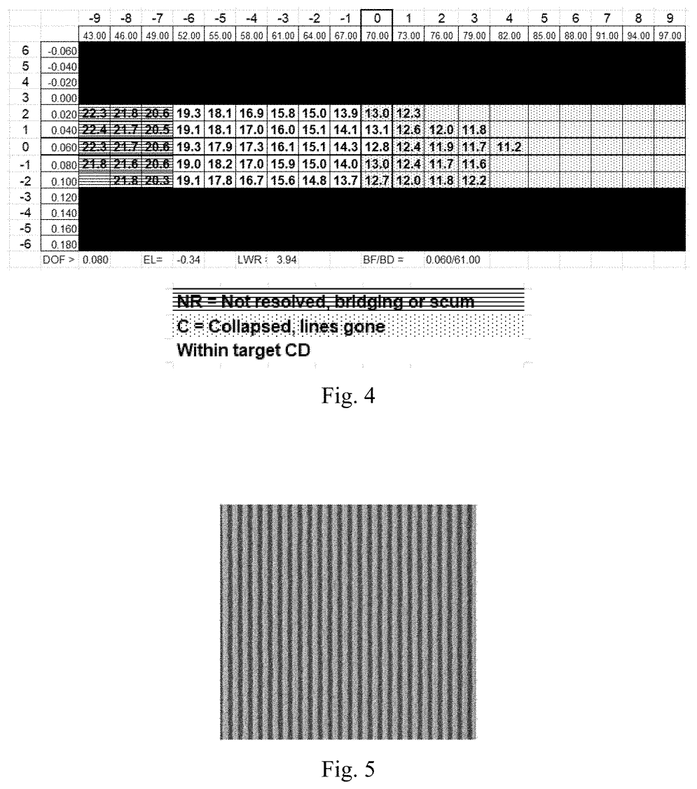

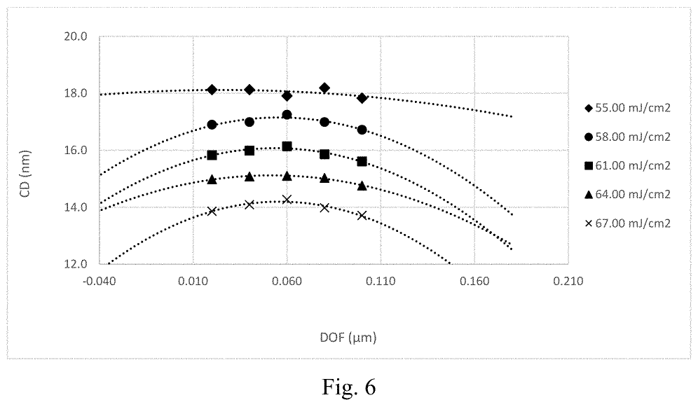

The material from Example 13 was spin coated at 1340 rpm for 30 seconds and baked at 205° C. for 60 seconds on top of a spin-on carbon layer of OptiStack® SOC120 material (Brewer Science, Rolla, Mo.), which was coated on a Si wafer by spin coating at 1,406 rpm for 30 seconds and baking at 205° C. for 60 seconds to form a 25-nm film. An EUV resist (JSR4267, available from JSR Corporation; supplied by IMEC) was coated onto the hardmask layer by spin coating at 1,040 rpm for 25 seconds, and then baking at 130° C. for 60 seconds to form a 35-nm thick coat. The formed resist was exposed using an EUV scanner (TWINSCAN NXE:3400B, available from AMSL) for the imaging step and a track sold under the name CLEAN TRACK™ LITHIUS Pro™ Z (by TEL, Tokyo, JP) for the wafer process. After exposure, a 110° C. bake for 60 seconds was performed. The pattern was then developed with a developer (OPD262 available from FujiFilm). The resulting features were analyzed using a scanning electron microscope (CG5000-2, Hitachi) using 500 V and 8 pA at 164Kx magnification. FIG. 4 shows the exposure matrix, FIG. 5 shows a top-down view of the sample, and FIG. 6 shows the Bossung curve for the Example 13 material.

### Example 17

### Synthesis of Poly(tris[3-(trimethoxysilyl)propyl] isocyanurate)

In a 100-ml round bottom flask, 6.16 grams of tris[3-(trimethoxysilyl)propyl] isocyanurate (Gelest, Morrisville, Pa.) and 17 grams of PGME (KMG Electronic Chemicals, Fort Worth, Tex.) were added. Next, 0.88 gram of 0.01 N HNO3 (Sigma-Aldrich Inc., St. Louis, Mo.) were added dropwise while stirring at room temperature for 30 minutes. The mixture was heated to reflux at 90° C. for 20 minutes followed by cooling to room temperature and stored at −20° C.

### Example 18

### Formulation of Si-HM with Example 17 Polymer

In a 1-liter Aicello bottle, 5.43 grams of the mother liquor synthesized in Example 17, 0.11 gram of 2% TBPB/PGME stock solution (TBPB from Sigma-Aldrich Inc., St. Louis, Mo.), 1.09 gram of 2% maleic acid/PGME stock solution (pH regulator; maleic acid from Sigma-Aldrich Inc., St. Louis, Mo.), 257.18 grams of PGME, and 29.19 grams of PGMEA were added and mixed together for 30 minutes. This formulation was filtered using a 0.1-micron filter.

### Example 19

### EUV Line/Space (L/S) Patterning Results of Example 18 Formulation

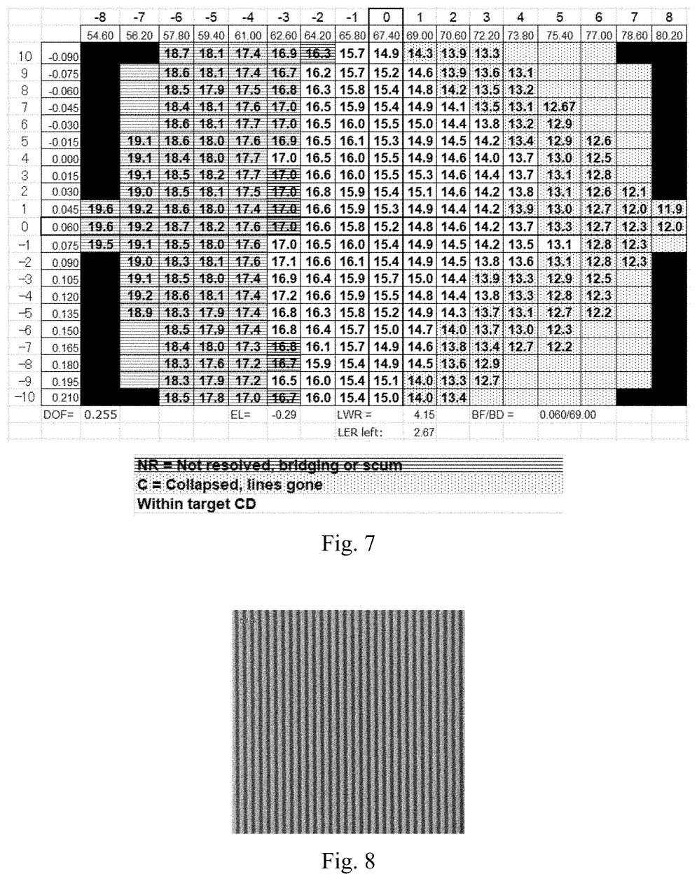

The material from Example 18 was spin coated at 1521 rpm for 30 seconds and baked at 205° C. for 60 seconds on top of a spin-on carbon layer (sold under the name OptiStack® SOC120, by Brewer Science, Rolla, Mo.), which was coated on a Si wafer by spin coating at 1,521 rpm for 30 seconds and baking at 205° C. for 60 seconds to form a 25-nm film. An EUV resist (JSR4267, available from JSR Corporation; supplied by IMEC) was then coated by spin coating at 1,040 rpm for 25 seconds, followed by baking at 130° C. for 60 seconds to form a 35-nm thick coat. The formed resist was exposed using an EUV scanner (TWINSCAN NXE:3400B, available from AMSL) for the imaging step and a track sold under the name CLEAN TRACK™ LITHIUS Pro™ Z (by TEL, Tokyo, JP) for the wafer process. After exposure, a 110° C. bake for 60 seconds was performed. The pattern was then developed with a developer (OPD262 available from FujiFilm). The resulting features were analyzed using a scanning electron microscope (CG6300, Hitachi) using 500 V and 8 pA at 164Kx magnification. FIG. 7 shows the exposure matrix for L/S patterning, and FIG. 8 shows a top-down view of the printed L/S sample.

### Example 20

### EUV Contact Hole Patterning of Example 18 Formulation

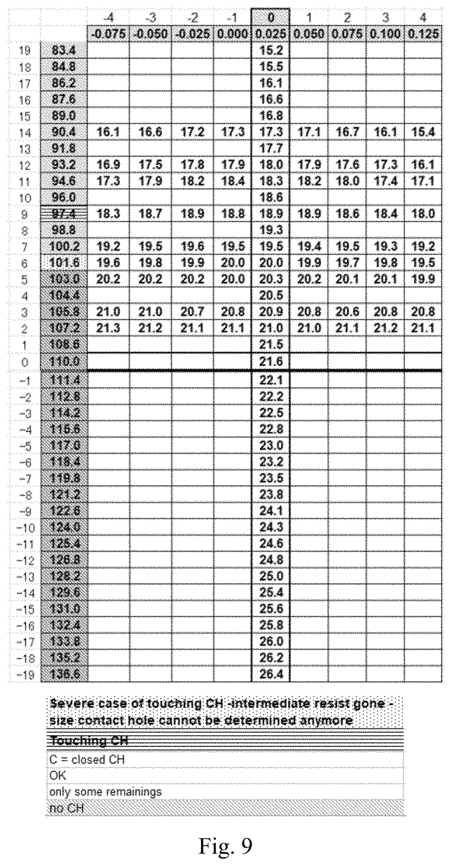

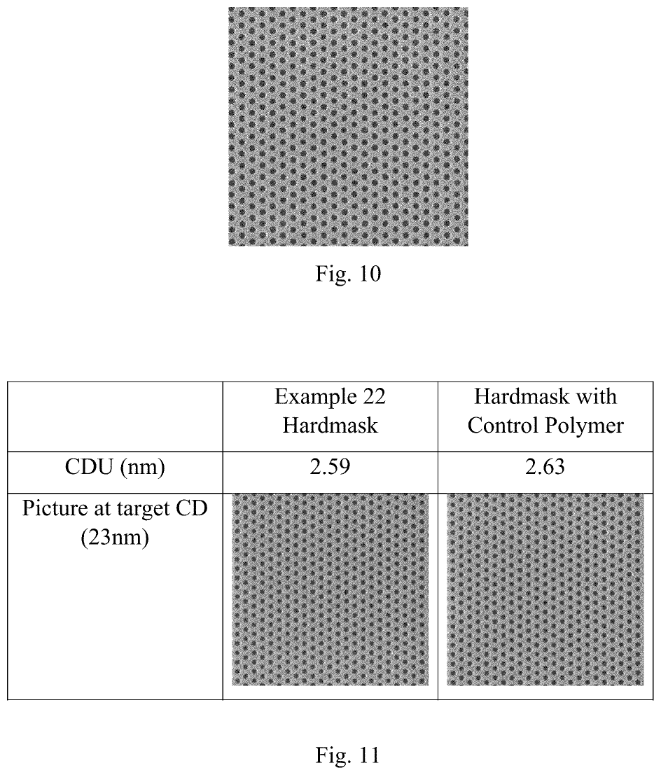

The material from Example 18 was spin coated onto a bare silicon wafer at 1,900 rpm for 30 seconds and baking at 205° C. for 60 seconds to form a 5-nm thick hardmask layer. An EUV resist (JSR4267, available from JSR Corporation; supplied by IMEC) was coated on the hardmask layer by spin coating at 1,040 rpm for 25 seconds followed by baking at 130° C. for 60 seconds to form a 35-nm thick layer of resist. The formed resist was exposed using an EUV scanner (TWINSCAN NXE:3400B, available from AMSL) for the imaging step and a track sold under the name CLEAN TRACK™ LITHIUS Pro Z (by TEL, Tokyo, JP) for the wafer process. After exposure, a 110° C. bake for 60 seconds was performed. The pattern was then developed with a developer (OPD262 available from FujiFilm). The resulting features were analyzed using a scanning electron microscope (CG6300, Hitachi) using 500 V and 8 pA at 164Kx magnification. FIG. 9 shows the exposure matrix for contact hole patterning, and FIG. 10 shows a top-down view of the printed contact hole features.

### Example 21

### Formulation of Si-HM with Example 17 Polymer

In a 250-ml Aicello bottle, 8.85 grams of the mother liquor synthesized in Example 17, 1.77 grams of 2% maleic acid/PGME stock solution, 145.72 grams of PGME, and 17.17 grams of PGMEA were added and mixed together for 30 minutes. This formulation was filtered using a 0.1-micron filter.

### Example 22

### EUV Contact Hole Patterning of Example 21 Formulation

The material from Example 21 was spin coated onto a bare silicon wafer at 1,900 rpm for 30 seconds and baking at 205° C. for 60 seconds to form a 5-nm thick hardmask layer. An EUV resist (JSR4267, available from JSR Corporation; supplied by IMEC) was coated on the hardmask layer by spin coating at 1,040 rpm for 25 seconds, and then baking at 130° C. for 60 seconds to form a 35-nm thick resist layer. The resist was then exposed using a EUV scanner (TWINSCAN NXE:3400B, available from AMSL) and developed with OPD262 developer for 20 seconds. Critical dimension uniformity (“CDU”) for the pattern was analyzed by CD-SEM measurements (Hitachi CG5000-2, 150Kx; Beam=500 V, 8 pA) and compared to a linear control polymer formed from tris[3-(trimethoxysilyl)propyl] isocyanurate, tetraethylorthosilicate (TEOS), and phenyltrimethoxysilane that was applied using the same parameters as the material from Example 21. The CDU information and SEM images for each polymer is shown in FIG. 11.

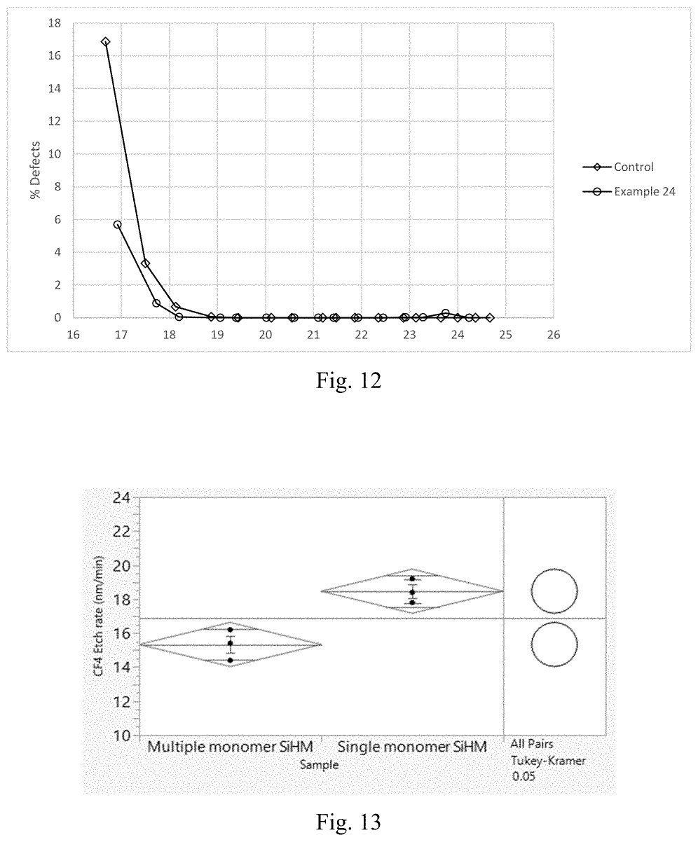

The defect-free process window was analyzed using Kolona software on a total of 8,600 contact holes and compared to the control. This data is shown in FIG. 12, where the x-axis shows the diameter of the features in nanometers.

### Example 23

### Etch Results for Example 13 Formulation

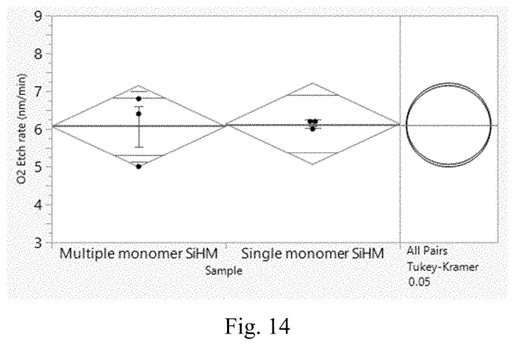

The material from Example 13 and a conventional (multiple-monomer) Si-HM sample with a 2:1 ratio of methyltrimethoxysilane and vinyltrimethoxysilane which was designed to have similar functional groups as the polymer used in Example 13 (i.e., 1,2-bis(methyldiethoxysilyl)ethylene) were tested for etch rates in O₂- and CF₄-based plasma etch chemistries. Samples were spin coated on 100-mm silicon wafers, baked at 205° C. for 60 seconds, diced into 2.5-mm×2.5-mm chips, and then etched using an Oxford Plasma Lab 80+ etcher. An O₂-based etch was used with one set of these chips, and a CF₄-based etch was used with another set of these chips. Settings for the etch process were 50 sccm flow rate (O₂ or CF₄), 50 mTorr chamber pressure, 50 W power, and 30 seconds etch time. Film thickness measurements from before and after etching, taken with a Gaertner ellipsometer, were used to calculate the etch rates of the samples with the two etch chemistries. These etch rate results are shown in FIGS. 13 and 14, with the multiple-monomer material on the left, and the single-monomer material (i.e., Example 13 formulation) on the right.

Results for the CF₄ etch rate show the single-monomer polymer sample has a higher etch rate (18.47 nm/min) than the conventional multiple-monomer Si-HM sample. A higher CF₄ etch rate is desirable during semiconductor processing with a Si-HM. With O₂ plasma, the average etch rates are equivalent for the two samples, but the single-component polymer sample exhibited a reduced variation in etch rate (standard deviation of 0.115 nm/min) as compared to the conventional Si-HM sample (standard deviation of 0.945 nm/min), which would result in more uniform etch and better definition of features.

We claim:

1. A method of forming a structure, said method comprising:
providing a substrate, said substrate optionally including one or more intermediate layers thereon;
applying a composition to said substrate, or on said one or more intermediate layers on said substrate, if present, so as to form a silicon hardmask layer, said composition comprising a first polymer or oligomer formed from a monomer comprising at least two of moiety (I): 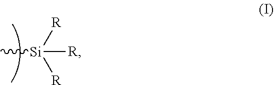
where:
each R is individually chosen from hydrogen, alkyls, alkoxys, and halogens; and
“ [symbol] ” represents the point of attachment of the silicon atom to the rest of the monomer;
optionally forming one or more intermediate layers on said silicon hardmask layer;
forming a photoresist layer on said one or more intermediate layers on said silicon hardmask layer, if present, or on said silicon hardmask layer if no intermediate layer is present; and
subjecting at least a portion of said photoresist layer to radiation.

2. The method of claim 1, wherein said first polymer or oligomer does not include any Si—OH groups.

3. The method of claim 1, wherein said composition does not include any polymers other than said first polymer.

4. The method of claim 1, wherein said first polymer or oligomer does not include [3-(triethoxysilyl)propyl] succinic anhydride monomers.

5. The method of claim 1, wherein said first polymer or oligomer comprises at least about 95% of a single monomer type.

6. The method of claim 1, wherein said first polymer or oligomer consists of a single monomer type.

7. The method of claim 1, wherein said first polymer or oligomer is formed from monomers comprising one or both of the following structures: 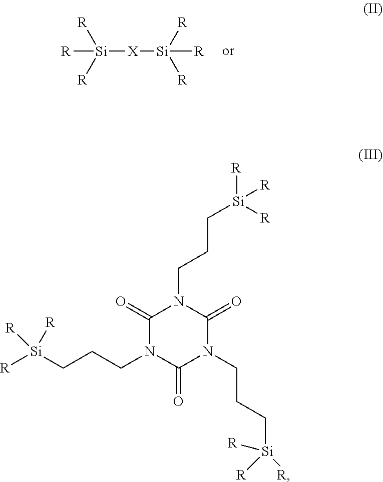
where X is chosen from one or more of: 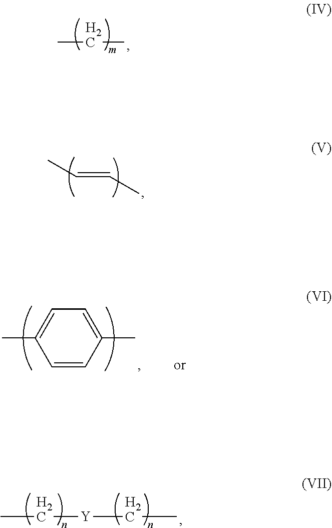
where:
m is 1 to about 16;
n is 1 to about 8; and
each Y is individually chosen from one or more of: 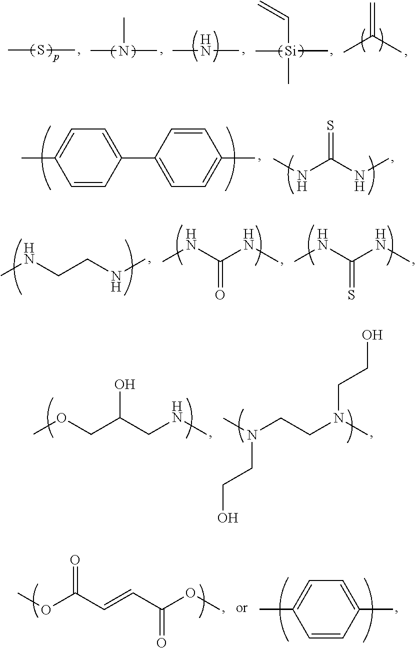
where p is 1 to 6.

8. The method of claim 1, wherein said first polymer or oligomer is formed from one or more of 1,2-bis(triethoxysilyl)ethylene, 1,2-bis(methyldiethoxysilyl)ethylene, 1,1-bis(trimethoxysilylmethyl)-ethylene, 1,6-bis(trimethoxysilyl)hexane, 1,4-bis triethoxysilylbenzene, 1,2-bis(trimethoxysilyl)-ethane, n,n′-bis[3-(triethoxysilyl)propyl]urea, n,n′-bis[3-(triethoxysilyl)propyl]thiourea, 1,8-bis(triethoxysilyl)octane, bis(triethoxysilyl)methane, bis(trimethoxysilylethyl)benzene, 1,3-bis(chlorodimethylsilyl)propane, 1,2-bis(chlorodimethylsilyl)ethane, bis[3-(triethoxysilyl)-propyl] disulfide, n,n′-bis[(3-trimethoxysilyl)propyl] ethylenediamine, n,n′-bis(2-hydroxyethyl)-n,n′-bis(trimethoxysilylpropyl)ethylenediamine, bis(methyldimethoxysilylpropyl)-n-methyl-amine, bis[3-(triethoxysilyl)propyl]tetrasulfide, bis(triethoxysilylethyl)-vinylmethylsilane, bis(3-trimethoxysilylpropyl) fumarate, 4,4′-bis(dimethylsilyl)biphenyl, n,n′-bis(3-trimethoxysilylpropyl)thiourea, 1,11-bis(trimethoxysilyl)-4-oxa-8-azaundecan-6-ol, bis(methyldiethoxysilylpropyl)amine, or tris[3-(trimethoxysilyl)propyl] isocyanurate.

9. The method of claim 1, wherein said polymer comprises recurring units of one or both of: 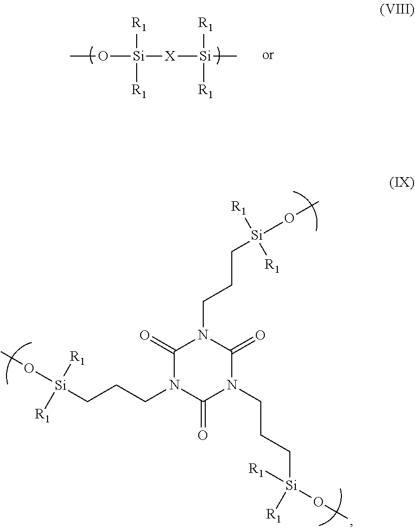
where each R₁ is individually chosen from hydrogen, alkyls, alkoxys, halogens, and —O—.

10. The method of claim 1, wherein said substrate is selected from the group consisting of as silicon, SiGe, SiO₂, Si₃N₄, SiON, SiCO:H, tetramethyl silate and tetramethyl-cyclotetrasiloxane combinations, aluminum, tungsten, tungsten silicide, gallium arsenide, germanium, tantalum, tantalum nitride, Ti₃N₄, hafnium, HfO₂, ruthenium, indium phosphide, coral, glass, and mixtures of the foregoing.

11. The method of claim 1, where said radiation is EUV radiation.

12. The method of claim 1, further comprising forming a pattern in said photoresist layer after said subjecting said photoresist layer to radiation.

13. The method of claim 12, further comprising transferring said pattern to said silicon hardmask layer, to said intermediate layers, if present, and to said substrate.

14. The method of claim 1, wherein an intermediate layer is present, and said intermediate layer is a carbon-rich layer.

15. A structure comprising:
a substrate having a surface;
one or more optional intermediate layers on said substrate surface;
a silicon hardmask layer on said substrate surface, or on said intermediate layers on said substrate surface, if present, said silicon hardmask layer comprising a polymer or oligomer that comprise recurring units of one or both of: 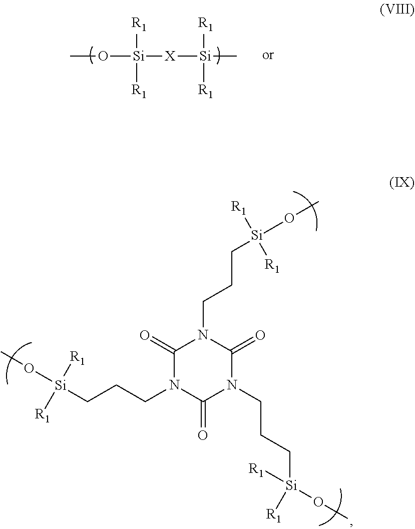
where:
each R₁ is individually chosen from hydrogen, alkyls, alkoxys, halogens, and —O—;
X is chosen from: 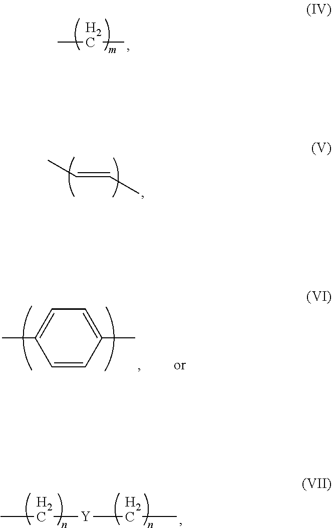
where:
m is 1 to about 16;
n is 1 to about 8; and
each Y is individually chosen from one or more of: 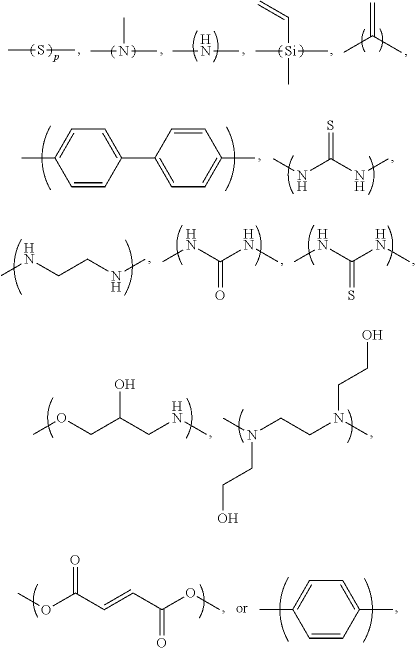
where p is 1 to 6;
one or more optional intermediate layers on said silicon hardmask layer; and
a photoresist layer on said one or more intermediate layers on said silicon hardmask layer, if present, or on said silicon hardmask layer if no intermediate layer is present.

16. The structure of claim 15, wherein said substrate is selected from the group consisting of as silicon, SiGe, SiO₂, Si₃N₄, SiON, SiCO:H, tetramethyl silate and tetramethyl-cyclotetrasiloxane combinations, aluminum, tungsten, tungsten silicide, gallium arsenide, germanium, tantalum, tantalum nitride, Ti₃N₄, hafnium, HfO₂, ruthenium, indium phosphide, coral, glass, and mixtures of the foregoing.

17. The structure of claim 15, wherein said silicon hardmask layer and said photoresist layer have respective etch rates in CF₄, said silicon hardmask layer etch rate in CF₄ being at least about 1.5 times said photoresist layer etch rate in CF₄.

18. The structure of claim 15, wherein said silicon hardmask layer has an etch rate in O₂, and the standard deviation between three etch rate measurements is less than about 0.5 nm/min.

19. The structure of claim 15, wherein said polymer or oligomer consists of a single monomer type.
